(19) United States
(12) Patent Application Publication
(10) Pub. No.: US 2024/0069087 A1
(43) Pub. Date: Feb. 29, 2024

(54) Real-Time Fault Detection and Infrared Inspection System

(71) Applicant: Darryl Mendivil, San Luis Obispo, CA (US)

(72) Inventor: Darryl Mendivil, San Luis Obispo, CA (US)

(21) Appl. No.: 18/365,747

(22) Filed: Aug. 4, 2023

Related U.S. Application Data
(63) Continuation-in-part of application No. 17/173,144, filed on Feb. 10, 2021.

(51) Int. Cl. G01R 31/08; B60W 60/00

(52) U.S. Cl. CPC G01R 31/085; B60W 60/001; B60W 2300/14; B60W 2420/42

(57) ABSTRACT

A Real-Time Fault Detection and Infrared Inspection System includes both a fixed imaging system and a mobile imaging system that includes a visual imaging device paired with an infrared imaging device which together can provide both visual and heat-detecting monitoring of anything within its field of view. The fixed imaging system is mounted to the top of a transmission tower and directed to view the transmission lines leading to and from the tower, while the mobile imaging system will allow for a supervision of a power generation or power distribution center. In both cases that imaging system will enable an operator to remotely access the imaging devices to visually inspect and to infrared inspect the system, checking for physical damage as well as excessive heat areas.

### PRIOR APPLICATIONS

This application is a continuation-in-part of U.S. patent application Ser. No. 17/173,144, filed on Feb. 10, 2021, entitled “Real-Time Fault Detection and Infrared Inspection System”, and which claims the benefit of priority to U.S. Provisional Patent Application Ser. No. 62/972,640, entitled “Real-Time Fault Detection and Infrared Imaging System,” filed on Feb. 10, 2020, the entirety of which is hereby incorporated by reference. This application is a continuation of U.S. Provisional Patent Application Ser. No. 63/370,384, entitled “Mobile and Substation Infrared Inspection System,” filed on Aug. 4, 2022, the entirety of which is hereby incorporated by reference.

### FIELD OF THE INVENTION

The present invention relates generally to fault detection systems. The present invention is more particularly related to the identification and classification of fault detection in high voltage electrical transmission lines and other power distribution equipment exhibiting higher than normal operating temperatures or point failures. The present invention is well suited for the real-time monitoring of high voltage transmission lines and other power distribution equipment using fixed and portable imaging systems to accurately and efficiently identify conditions that can lead to fire, system failure or other undesired system conditions.

### BACKGROUND OF THE INVENTION

In modern times, the world operates on electricity. Generally, the electricity that is used throughout the world is generated in more localized generation areas, such as steam generation plans, hydroelectric dams, solar farms, wind generation turbines, or a traditional coal powered power generation system. Regardless of what type of system is used to generate the electricity, the generation location is seldom adjacent the area of consumption. As a result, there is a need in the world where electricity generated in one location, is transmitted to other areas needing the electricity. Oftentimes this electricity is transmitted using overhead wires which are generally high voltage in the tens of thousands of volts, and which can span hundreds if not thousands of miles. Indeed, electricity generated in one country is often transmitted to other countries having a need.

The typical method by which high voltage electricity is transmitted across the globe includes a high voltage electrical transmission line where those lines are suspended high above the earth and often consist of many individual conductors which each carry an electrical voltage and in combination can deliver a voltage to a destination, such as a localized distribution center. These localized distribution centers are often placed where the power is ultimately needed, such as in municipalities, neighborhoods, manufacturing facilities and the like.

Since these high voltage electrical transmission lines span hundreds if not thousands of miles, it is common for these lines to be located in remote areas where easy access for inspection and maintenance is not available. In these areas, the transmission lines are often left uninspected, and only when a system fault occurs do inspection personnel actually visit and inspect the area. Unfortunately, these system faults can occur due to corrosion, stretching of the lines, insulator degradation, high seasonal temperatures, damaging winds, or a host of other challenges inherent in high voltage transmission of electricity. With these faults come the possibility that the fault will result in fires being started either on the transmission line, on the supporting electrical tower structures, or in some cases, in the neighboring vegetation. The neighboring vegetation fires often cause the most damage. For instance, when a fault occurs in a remote location, such as in a heavily forested mountain region, the fault can ignite neighboring vegetation, and that fire being in a remote and generally inaccessible region, may go on for some time before being detected. Unfortunately, this delay can and does result in the loss of enormous forest areas, loss of countless properties in rural areas, and most unfortunately, the loss of wildlife and human life due to the unexpected and uncontrolled wildfire.

In light of the above, it would be advantageous to provide a real-time monitoring system that enables the organizations monitoring high voltage transmission lines, such as municipalities or energy companies, to maintain inspection of all locations of an electrical distribution network to provide immediate notification of pre-fault conditions such that organization may assess the risk prior to a fault condition occurring and the triggering of the negative consequences outlined above. It would also be advantageous to provide a system that is easily installed, easily maintained, easily operated, and relatively cost effective. It would also be advantageous to provide both fixed and portable solutions to accommodate those high voltage transmission line installations which are both accessible, and inaccessible to the maintenance and monitoring crews. It would also be advantageous if the monitoring system had features which would allow for use as a security system, which could send autonomous alerts with instant problem identification, such as station entry or high energy event based on image recognition software.

While there is current monitoring available for power distribution equipment, it is not without its own set of issues. Currently, the most common method of monitoring these facilities is through on-site visual and thermal imaging inspection. The main shortfall with this current method is the variation that is introduced with each inspection; resulting in inaccurate, and unreliable results. This variance results to a number of different factors such as the person conducting the inspection is standing in a different location each time, or the inspections are conducted at different times of the day.

It is important to improve the monitoring capabilities for power distribution equipment because periodic inspections are not efficient. If an inspection does not identify potential issues, then incidents like mechanical issues, outages, or fires cannot be reasonably prevented. Power distribution equipment is frequently placed in electrical substations that are located in commercial and/or residential areas. If a failure or fire is not detected early, then potentially catastrophic damage could result.

In light of the above, it would be advantageous to have a monitoring system that was designed to meet the requirements to monitor power generation equipment. It would also be advantageous to provide a system that is easily installed, maintained, and operated, while remaining relatively cost effective. It would also be advantageous to provide both fixed and portable solutions to accommodate the different layouts of power distribution equipment located in any given electrical substation which is accessible to the maintenance and monitoring crews. It would also be advantageous if the monitoring system had features which would allow for use as a security system, which could send alerts with instant problem identification, such as station entry or high energy event based on image recognition software.

### SUMMARY OF THE INVENTION

The Real-Time Fault Detection and Infrared Inspection System of the present invention includes a fixed imaging system that includes a visual imaging device paired with an infrared imaging device which together can provide both visual and heat-detecting monitoring of anything within its field of view. In a preferred embodiment, this fixed imaging system is mounted to the top of a transmission tower and directed to view the transmission lines leading to and from the tower such that an operator can remotely access the imaging devices to visually inspect and to infrared inspect the system, checking for physical damage as well as excessive heat areas.

Typically, when an electrical transmission line is experiencing early failures, such as corrosion, stretching, or physical damage, that area adjacent the damage becomes hotter than the adjacent components of the system. For instance, when a splice (junction between two ends of a transmission cable) begins to corrode and fail, the electrical resistance of splice increases. Since the resistance increases, the current through that resistance causes an increase in the heat at that splice location as compared to the transmission line itself. In significant circumstances, this heat can cause the splice to melt, catch fire, or otherwise catastrophically fail which can result in a live transmission line falling to the ground igniting its surroundings. In other circumstances, the failure is explosive in nature, and the sparks ignite the surroundings.

The Real-Time Fault Detection and Infrared Inspection System of the present invention monitors every location of an electrical transmission system, and detects these faults through the presetting of fault conditions. These preset fault conditions are triggered when an area under surveillance passes a preset threshold for infrared heat, and warnings are automatically sounded to provide the operators immediate notice of a fault condition, thus providing an emergency response to either shut the system down, summon repair crews, notify local residents, or bypass a trouble location. Regardless of the action taken, the operator is in full control with immediate information of a fault condition before it escalates to something catastrophic.

In addition to the fixed imaging system, the Real-Time Fault Detection and Infrared Inspection System of the present invention includes both vehicle mounted detection systems, as well as hand-operated systems. These vehicle and hand systems cooperate with the fixed systems to provide an operator the ability to inspect an entire electrical transmission and distribution system easily and routinely.

Each of the imaging systems of the Real-Time Fault Detection and Infrared Inspection System of the present invention includes the ability to access and report a global positioning satellite (GPS) location which, when coupled with the visual image of the area experiencing a fault, and the infrared image of the heat profile, provides the operator with a pinpoint location of the fault, and visual appearance of the fault location, and a heat index image of the fault condition giving rise to the severity of the fault, and the associated risk of catastrophic failure or fire. The Real-Time Fault Detection and Infrared Inspection System of the present Invention provides operators a system to effectively monitor every inch of a distribution network, and thereby significantly limit the risk of catastrophic failures due to damage or maintenance-related faults.

In an alternative embodiment, Real-Time Fault Detection and Infrared Inspection System is designed to be a mobile inspection unit. This embodiment of the Real-Time Fault Detection and Infrared Inspection System will be useful for the supervision of electrical substations. The mobile inspection unit will be made up by an imaging system, an extendable mast, and a movable base. This embodiment of the Real-Time Fault Detection and Infrared Inspection system will allow for the system as a whole to become portable and easily relocated to different locations based on the need of any given situation.

The movable base for the mobile inspection system will be capable of providing twenty-four hour visual and thermal monitoring. The thermal camera will be useful for identifying points of interest at risk of electrical failure, while the visual camera will be useful for monitoring mechanical issues, smoke from fires, and unauthorized access to the facility. No matter the data that is collected, the information will be processed by the control system installed onto the movable base. This data will also be able to be accessed in real-time for operators, or be sent to a remote-control station to trigger alarms.

The movable base for the mobile inspection unit can be made from a number of different options. The first one is that the movable base can be a towable trailer that can be moved from location to location by a vehicle with a tow hitch. Another one is that the movable base can be a semi-permanent platform which can be moved by a forklift or any other similar machine. The final one is that the movable base can consist of a solid platform with an RC unit and wheels mounted to the bottom; coupled with a navigation module, this unit would be capable of autonomous movement or be controlled by an operator.

The flexibility and compact design for the movable base will enable the mobile inspection unit to be efficient and effective in a number of different environments. In a non-limiting example, the mobile inspection unit will be particularly useful at power distribution plants, or power generation plants that have a high number of electrical equipment that are at risk of overheating in addition to transmission lines. The mobile inspection unit can be easily accounted for in the design of new facilities, or more importantly, easily incorporated into existing sites. The mobile inspection unit can also be equipped with a variety of different security features in addition to the imaging equipment. These security features can include a two-way speaker that can be used for an alarm system, a spotlight mounted to a PTZ bracket, and a camera with facial recognition software. Further, the users of each system can customize the different kind of alerts they receive from the security features or imaging equipment.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a system-level drawing showing a typical high voltage electrical transmission line spanning between numerous transmission line towers in a rural area each equipped with the fixed imaging system of the present invention, and a few vehicle and hand-held imaging systems which together provide a system wide monitoring system for high voltage electrical transmission;

FIG. 2 is a system level drawing showing a single transmission line tower having a fixed imaging system looking downline and equipped with a communication link that can by wired or wireless connection, communicate to a communication center that interfaces with the digital cloud, a vehicle imaging system and a handheld imaging system that can likewise communicate to a communication center and is configured to receive GPS data, and provide all communications bidirectionally to a control center having a number of remote monitoring stations through which operational personnel can monitor real time data of the electrical transmission lines being monitored;

FIG. 3 is a representative example of a monitoring station of the Real-Time Fault Detection and Infrared Inspection System of the present invention and can be configured to display both a visual image field, and an infrared image field;

FIG. 4 is an alternative representative example of a monitoring station of the Real-Time Fault Detection and Infrared Inspection System of the present invention showing the superposition of the visual image field over the infrared image field to provide an operator with a clear indication of the location and source of a possible fault condition;

FIG. 5 is a graphical representation of the video image data and an infrared image data depicting the detection of a fault condition when the intensity of the infrared video signal passes a preset threshold, and provision of an alarm condition to the operator to take immediate action once the fault is detected;

FIG. 6 is a perspective view of the imaging system of the Real-Time Fault Detection and Infrared Inspection System of the present invention showing a rectangular chassis equipped with a dual imaging camera having a visual sensor and an infrared sensor, and equipped with an antenna for transmitting wireless signals, and a mounting base suitable for attachment to a pan, tilt and zoom (“PTZ”) base;

FIG. 7 is a front view of the imaging system of the Real-Time Fault Detection and Infrared Inspection System of the present invention showing the placement of the visual sensor and infrared sensor and surrounding chassis features;

FIG. 8 is a right side perspective view of the imaging system of the Real-Time Fault Detection and Infrared Inspection System of the present invention showing the locking features and PTZ attachment mount;

FIG. 9 is a right side view of the imaging system of the Real-Time Fault Detection and Infrared Inspection System of the present invention with a portion of the chassis shown in phantom to allow discussion of the camera and related heat sink configuration, upper and lower venting, and other internal features of the imaging system;

FIG. 10 is a view consistent with FIG. 9, with the phantom portion removed to depict the locking configuration;

FIG. 11 is a back right side view of the imaging system of the Real-Time Fault Detection and Infrared Inspection System of the present invention showing the rear of the camera and the cabling fasteners and access port, along with the upper and lower heat sinks used to distribute the heat from the camera;

FIG. 12 is an enlarged view of the imaging system of the Real-Time Fault Detection and Infrared Inspection System of the present invention with the lid removed and showing the camera, heat sink configuration and attachment, electrical connections for the camera, cabling fasteners, and camera interface to the front panel of the chassis;

FIG. 13 is a back right side view showing the lid and associated venting formed to create an air passage for the heated air leaving the heat sinks to rise and exit the chassis drawing fresh, cooled air, through the lower vent panel;

FIG. 14 is a preferred embodiment of the imaging system of the Real-Time Fault Detection and Infrared Inspection System of the present invention showing the chassis with the camera mounted to a PTZ mount and a base mounting bracket;

FIG. 15 is a front upper view of the imaging system of FIG. 14 with the lid open and showing the placement of the heat sink above the camera and the relative mounting positions of the chassis to the PTZ and base;

FIG. 16 is a back upper view of the imaging system of FIG. 14 with the lid open and showing the placement of the antenna interface cable and video output cable passing through the cable access port;

FIG. 17 is a back upper view again showing the placement of the antenna interface cable from the camera to the antenna;

FIG. 18 is a back upper view of the imaging system of the Real-Time Fault Detection and Infrared Inspection System of the present invention showing the chassis mounted to the PTZ mount and base ready for installation;

FIG. 19 is a flow chart depicting the method steps by which the Real-Time Fault Detection and Infrared Inspection System of the present invention is initiated, configured with preset fault condition limits, and then continuously monitors the electrical transmission lines to ensure proper, safe, and reliable operation, and if a fault occurs, provides an immediate alert, diagnoses the fault, and interrupts the circuit to prevent further damage;

FIG. 20 is a side view of the entire mobile embodiment of the Real-Time Fault Detection and Infrared Inspection System that shows the imaging system fixed to a telescoping mast that is mounted on a trailer and pulled by a vehicle;

FIG. 21 is a side view of the trailer and control system for the mobile version of the monitoring system discussed in FIG. 20;

FIG. 22 is a side view of the Mobile Inspection Unit with the telescopic mast in the raised position;

FIG. 23 is a side view of the Mobile Inspection Unit with the telescopic mast in the lowered position;

FIG. 24 is a back view of the mobile version of the Real-Time Fault Detection and Infrared Inspection System with the telescopic mast in the lowered position and mounted onto a semi-permanent base;

FIG. 25 is a front view of the imaging system for the Real-Time Fault Detection and Infrared Inspection System mounted atop a telescopic mast;

FIG. 26 is a side view of an alternative embodiment of the mobile version of the Real-Time Fault Detection and Infrared Inspection System mounted to a fully autonomous base; and

FIG. 27 is a flow chart outlining the operational sequence for the mobile version of the Real-Time Fault Detection and Infrared Inspection System;

### DETAILED DESCRIPTION

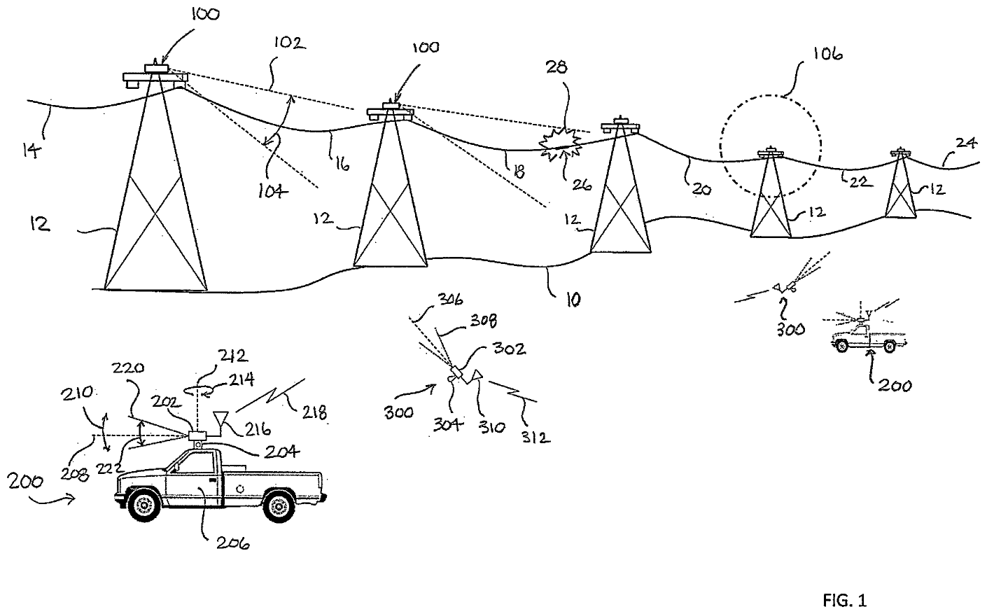

Referring initially to FIG. 1 a system-level drawing is shown and includes a typical high voltage electrical transmission line 14, 16, 18, 20, 22, 24 spanning between numerous transmission line towers 12 in a rural area 10 each equipped with the fixed imaging system 100 of the Real-Time Fault Detection and Infrared Inspection System of the present invention. Also in this Figure, a few vehicle 200 and hand-held 300 imaging systems are shown which together provide a system wide monitoring system for high voltage electrical transmission.

Fixed imaging system 100 has a field of view 102 with an angle 104 which, through lensing, can be selected for a particular application. For instance, when the separation between towers 12 is small (such as 100 yards), the angle 104 can be wide providing for a larger field of view. Alternatively, when the separation between towers 12 is large (such as 500 yards), the angle 104 can be narrow to view only the transmission line. In some applications, a varying focal lens may be used to provide a variable angle 104 to provide both wide angle viewing, and a more narrowed view, such as when zooming in on a possible fault location.

From this view, it is to be appreciated that a fault condition can occur. For instance, a splice 26 is depicted and, in a fault condition, exhibits a heat signature 28 which emits an infrared signal that is detected by the fixed imaging system 100. A more detailed description of the imaging system 100 follows below.

Vehicle mounted imaging system 200 includes an imaging device 202 mounted to a PTZ system 204 attached to a vehicle 206, and has a beam direction 208 that can be raised or lowered in direction 210. Likewise, imaging device 202 can be rotated about vertical axis 212 in direction 214 as needed to pan to a desired field of view 220. An antenna 216 is provided to allow radio communication 218 with a central command center, and the field of view 220 of the imaging device 202 can be adjusted 222. The vehicle mounted imaging system 200 can be driven through a transmission system, and the imaging device 202 can be panned left to right, and raised or lowered to obtain the best image possible of the transmission line system components.

Portable imaging system 300 includes an imaging device 302 having a handle 304 which has an imaging direction 306 and a field of view 308 such that a user can manually direct the imaging device 302 at transmission line system components to assess a possible fault condition. In the event a fault condition occurs, the imaging device 302 can use antenna 310 to communicate wirelessly 312 to a central command center.

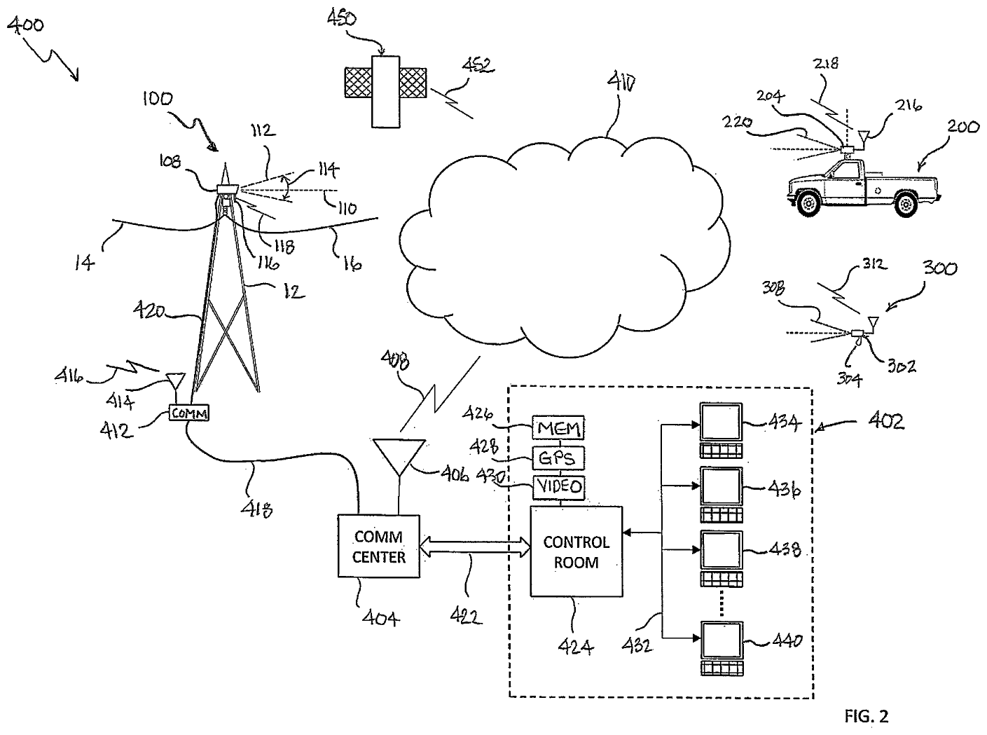

Referring now to FIG. 2, a Real-Time Fault Detection and Infrared Inspection System of the present invention is shown and generally designated 400. System 400 includes a single transmission line tower 12 supporting transmission lines 14 and 16, and is equipped with a fixed imaging system 100 looking downline. As shown, fixed imaging system 100 includes an imaging device 108 has a direction of view 110 with an image field 112 with a specific view angle 114. As described above, this view angle 114 can be pre-set in the form of a fixed lens, or it can be dynamic in the form of an adjustable focal length lens that will allow the broad view as well as a narrow view for component view or fault detection. Additionally, this imaging device 108 may be equipped with a PTZ component which allows the imaging 108 device to rotate in 360 degrees, pan and tilt upwards or downwards to allow a thorough inspection of all adjacent components of an electrical transmission line system.

A communication link is provided through a wired connection 420, or with antenna 116 through a wireless connection 118, and can communicate to a communication center 412 that interfaces through antenna 414 wirelessly via communications link 416 with the digital cloud 410. A vehicle imaging system 200 and a handheld imaging system 300 can likewise communication to a communication center 404 through antenna 406 or though other communication means known in the art. Communication from fixed imaging system 100 can also be routed via direct wiring 418 to a communication center 404, such as through routing over cabling also suspended from the transmission towers.

Communication center 404 is configured to receive GPS data 452 from a GPS network 450. As a result of the GPS receivers being present in each imaging device, it is possible to know the exact time, location and direction of travel of each imaging device of the system 400. The exact time, location and direction of travel of each imaging device of the system 400 can be communicated through link 408 and facilitates the immediate and pinpoint location of any fault detected, and minimizes the time delay in detection and resolution of faults, thereby minimizing the effects of a fault.

Each imaging device 100, 200, 300 of the Real-Time Fault Detection and Infrared Inspection System of the present invention communicates bidirectionally through communication link 422 to a control center 402 having a number of remote monitoring stations 434, 436, 438, 440 through which operational personnel can monitor real time data of the electrical transmission lines being monitored. As shown, control room 424 is equipped with system memory 426, a GPS interface 428, and a video storage and analysis module 430 which receives both visual and infrared video data for storage and analysis.

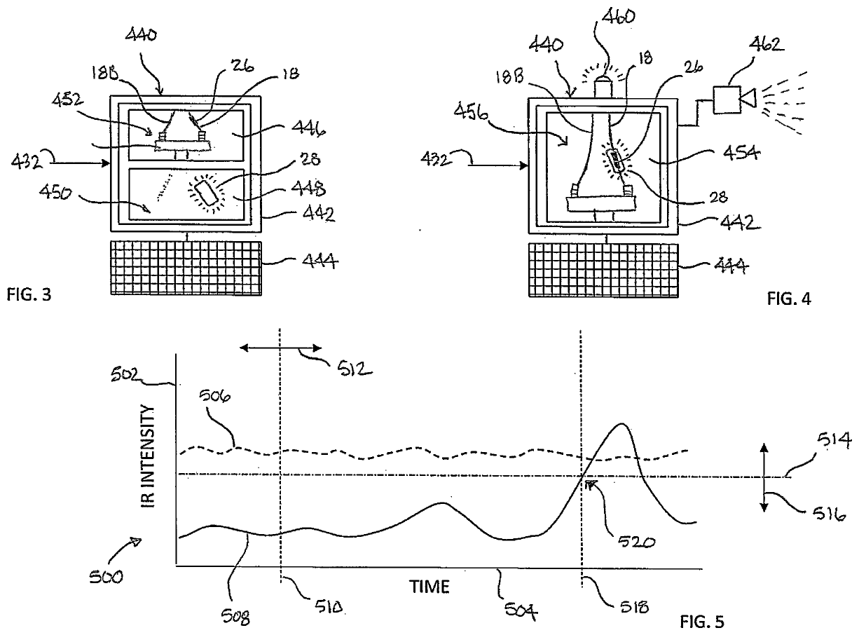

FIG. 3 is a representative example of a monitoring station 440 of the Real-Time Fault Detection and Infrared Inspection System of the present invention 400 having monitor 442 and a user interface 444. Monitoring stations, such as station 440 receives input from control room on communication link 432 and can be configured to display both a visual image field 446, and an infrared image field 448. As shown in image 452 of visual image field 446, a typical transmission tower support with insulators and a pair of electrical transmission lines 18 and 18B are shown leaving the conductor and having a splice 26. A corresponding infrared image field 448 is shown and depicts a high heat signature 28 in image 450. However, the infrared image alone is not always sufficient to identify the source of the heat. Accordingly, FIG. 4 is an alternative representative example of a monitoring station 440 of the Real-Time Fault Detection and Infrared Inspection System of the present invention 400 configured to show the superposition of the visual image field 446 over the infrared image field 448 to provide an operator with a clear indication of the location and source of a possible fault condition. Specifically, the visual image 452 is combined with the infrared image 450 to provide a combined image 456 that allows an operator to both see the visual image 452, and the heat signature 28, to pinpoint the failure in the visual field 454. For instance, in this exemplary image, the heat signature 28 is clearly associated with splice 26 giving the operator a confirmation that the splice is the fault location. If a heat signature 28 measured using the infrared imaging system exceeds a preset level, an audio alarm 462 and a visual alarm 460 can be triggered in order to alert the operational personnel of a fault condition and need for immediate action.

FIG. 5 is a representation of a graph 500 having an infrared intensity 502 against time 504 and plotted with the video image data 506 and an infrared image data 508 depicting the detection of a fault condition when the intensity of the infrared video signal 508 passes a preset threshold 514, and provide an alarm condition at instant 520 to the operator to take immediate action once the fault is detected. The infrared threshold limit 514 may be adjusted 516 for use in a variety of applications where the heat level may be acceptably higher or lower. For instance, in a high heat environment and high current, the infrared preset level may be higher, but in colder climates and lower current applications, the preset level may be lower. Time cursor 510 can be advanced through the video as recorded or monitored to provide a system monitor to pan through time 512 in order to focus attention on a particular video segment for analysis and fault detection, such as at time 518 where the infrared threshold limit 514 was exceeded.

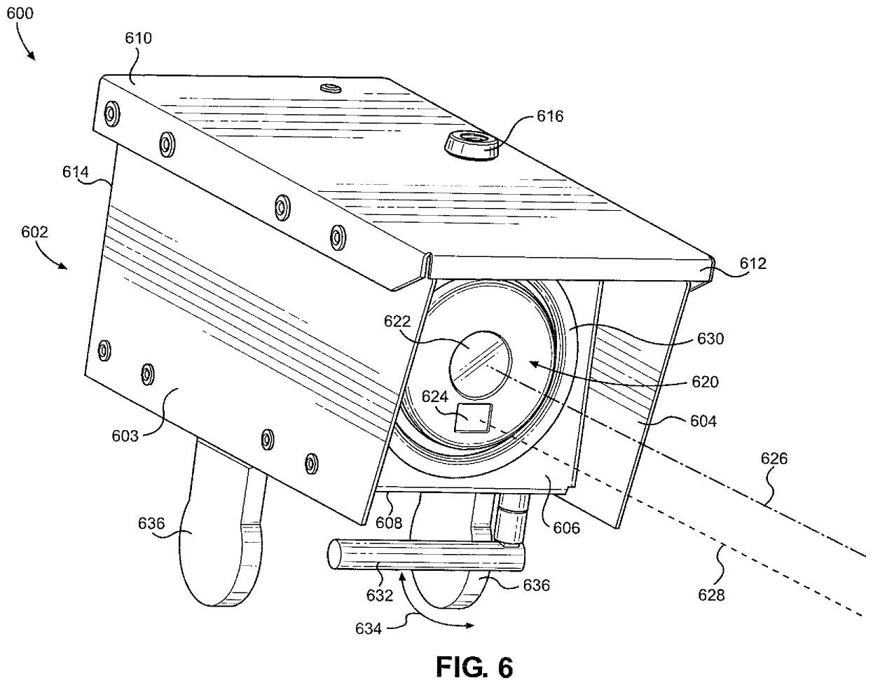

Referring now to FIG. 6, a perspective view of a preferred embodiment of the imaging system 600 of the Real-Time Fault Detection and Infrared Inspection System 400 of the present invention is shown. Imaging system 600 includes a rectangular chassis 602 having a left side 603, a right side 604, a front face 606, a bottom 608, a lid 610 having a drip edge 612 and a back 614. This exemplary chassis is not limiting, rather, it is an optimum design that is easily manufactured and durable and highly suitable for the instant imaging system.

Imaging system 600 is equipped with a dual imaging camera 620 having a visual sensor 624 and an infrared sensor 622 having an optical axis 628 and an infrared axis 626 respectively. Imaging system 600 is equipped with an antenna 632 that can be extended 634 for transmitting wireless signals, and a mounting base 636 suitable for attachment to a pan, tilt and zoom (“PTZ”) base. Lock 616 allows secure access to the contents of chassis 602.

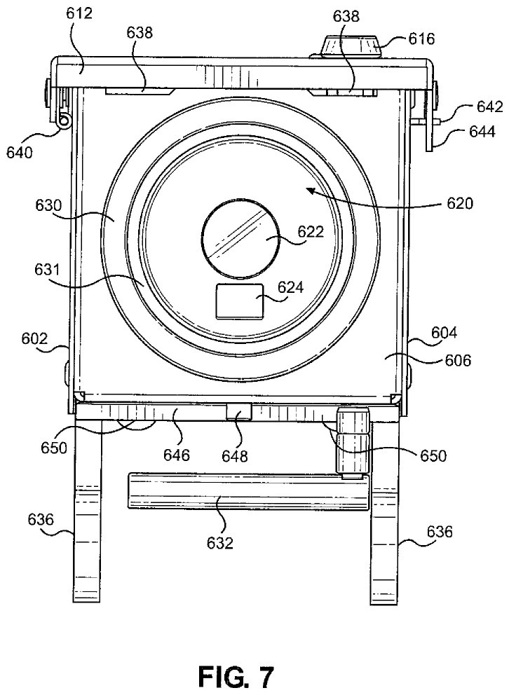

The front view of FIG. 7 shows the imaging system 600 of the Real-Time Fault Detection and Infrared Inspection System 400 of the present invention and the placement of the visual sensor 624 and infrared sensor 622 of camera 620. Also, chassis 602 features include vents 638, hinge 640 to allow opening of chassis 602, and locking tab 642 on flange 644 are shown.

FIG. 7 also shows the mounting of camera 620 in front panel 606 such that the infrared imaging device 624 and visual imaging device 622 are securely mounted to the chassis 602 which is attached to base 646 using attachment screw 648 to mount the camera 620 securely. Additional bolts 650 may be added for added strength of mounting chassis 602 to base 646. A sealing ring 630 is provided with a bellows 631 to provide for the sealed alignment of the camera 620 in chassis 602 while maintaining a clean seal around the camera 620. This provides a seal to prevent movement between the camera and the chassis, while also allowing the easy sealing without particular concern for precise alignment of the camera within the camera aperture formed in the front panel.

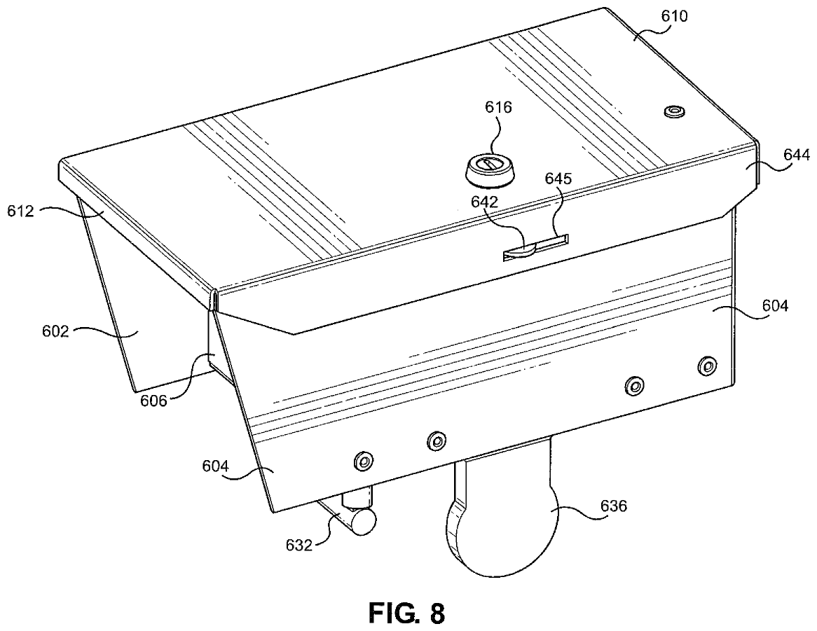

FIG. 8 is a right side perspective view of the imaging system 600 of the Real-Time Fault Detection and Infrared Inspection System 400 of the present invention showing the lock 616 with locking tab 642 in slot 645 and PTZ attachment mount 636.

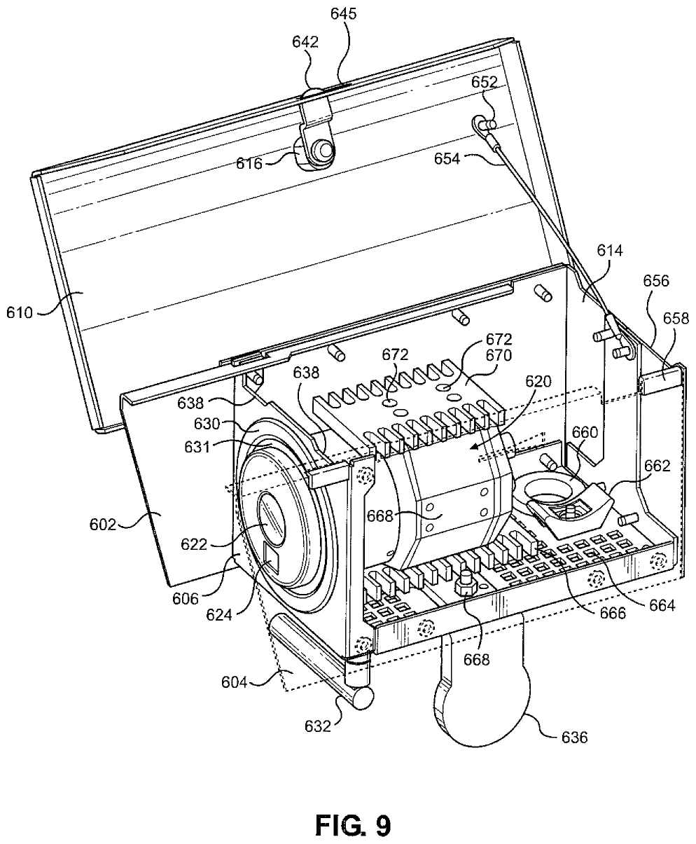

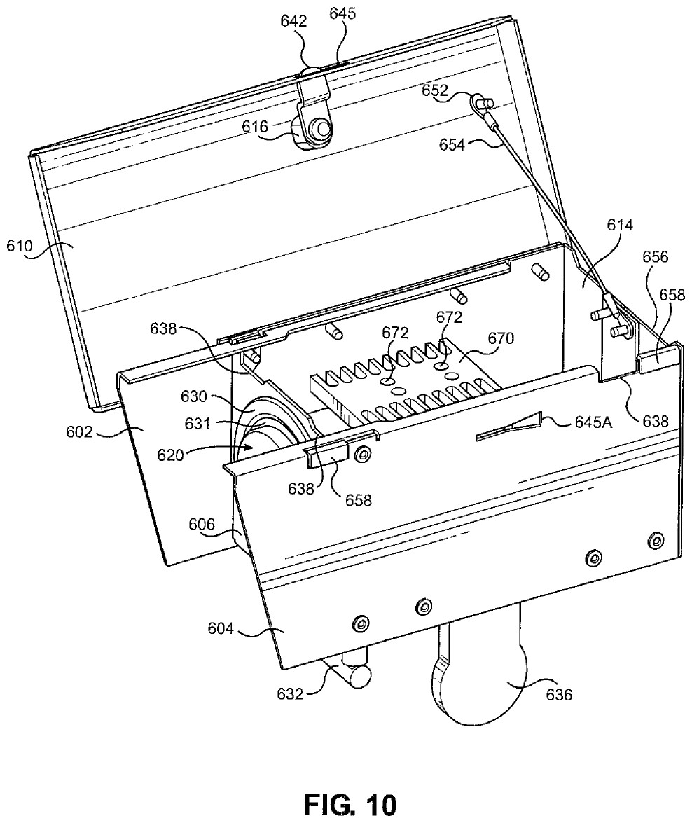

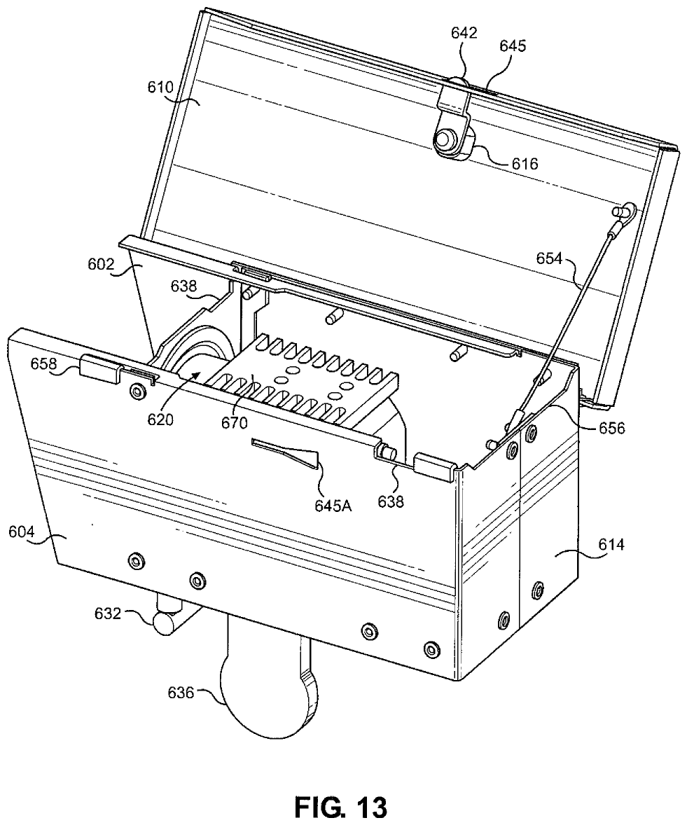

FIGS. 9 through 13 show the internal components of the imaging system 600 of the Real-Time Fault Detection and Infrared Inspection System 400 of the present invention. From this view, camera 620 can be clearly seen and is mounted on its upper and lower surfaces to a heat sink 666 and 670 using mounting fasteners 672. The lower heat sink 666 is attached to the base of chassis 602 using bolts 668 to attach the system 600 to the PTZ mount 636.

To provide for the proper ventilation of the camera 620 and dissipation of heat from heat sinks 666 and 670, vents 656 and 638 are formed in the front wall 606 and back wall 614 of chassis 602. A lid support line 654 extends from the chassis back wall 614 to fastener 652 on lid 610 to support the lid in the open position for maintenance and inspection. A locking slot 645A is formed to receive locking tab 642 when in the closed and locked position. Pads 658 are provided to provide a secure and rattle free enclosure which is particularly useful when operating the device 600 in rugged environments. Wiring aperture 660 and wire tie bracket 662 are provided to all the securing of cables that connect the camera 620 to the remainder of the system described herein. A wire tie can be used to secure a cable bundle to wire tie bracket 662. Additionally, vents 664 are formed in bottom panel of chassis to provide heat ventilation to cool the camera and related components. A bottom bracket 669 provides a base for mounting heat sink 666 using bolts 668 and further to secure camera 620 in place.

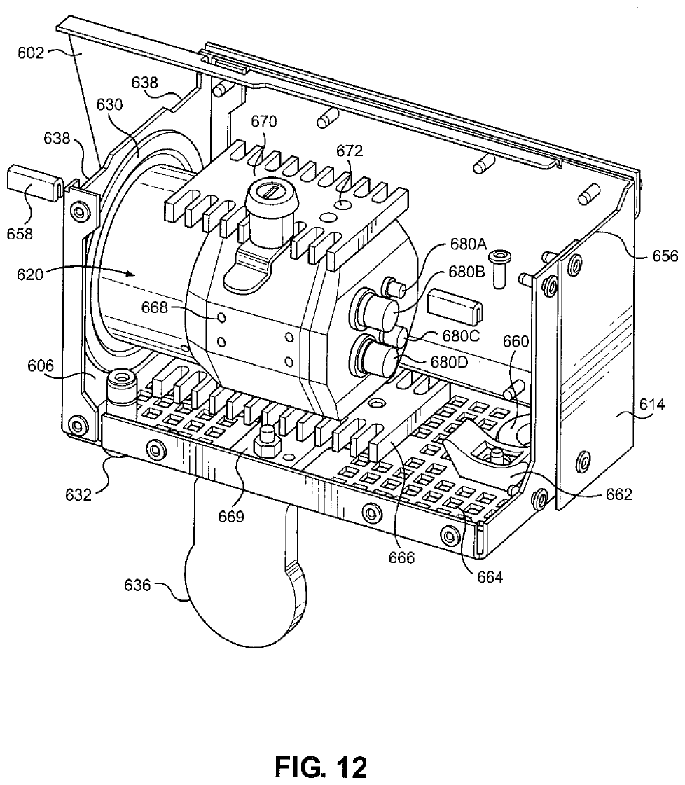

FIG. 12 is an enlarged view of the imaging system 600 of the Real-Time Fault Detection and Infrared Inspection System 400 of the present invention with the lid 610 removed and showing the camera 620, heat sink 666 and 670 configuration and attachment, and the various electrical connections for the camera 680A, 680B, 680C, and 680D. In a preferred embodiment, these electrical connections can include power over ethernet (PoE), RS232, Power input, radio frequency antenna connection, or other electrical connections known in the art and capable of transmitting necessary video signals and control to the communications center.

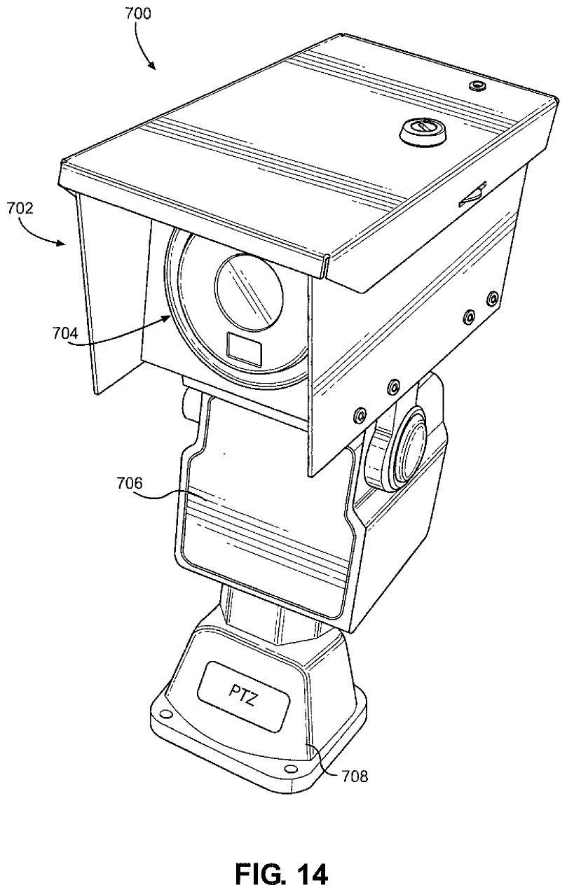

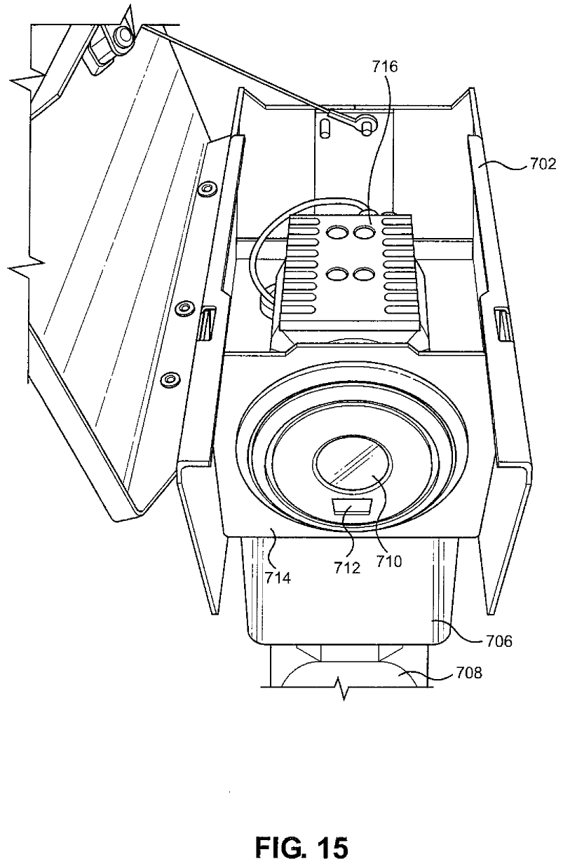

FIG. 14 is a preferred embodiment of the imaging system 700 of the Real-Time Fault Detection and Infrared Inspection System 400 of the present invention showing the chassis 702 with the camera 704 mounted to a PTZ mount 706 and a base mounting bracket 708. FIG. 15 shows a front upper view of the imaging system of FIG. 14 with the lid open and showing the placement of the heat sink 716 above the camera and the relative mounting positions of the chassis to the PTZ 706 and base 708.

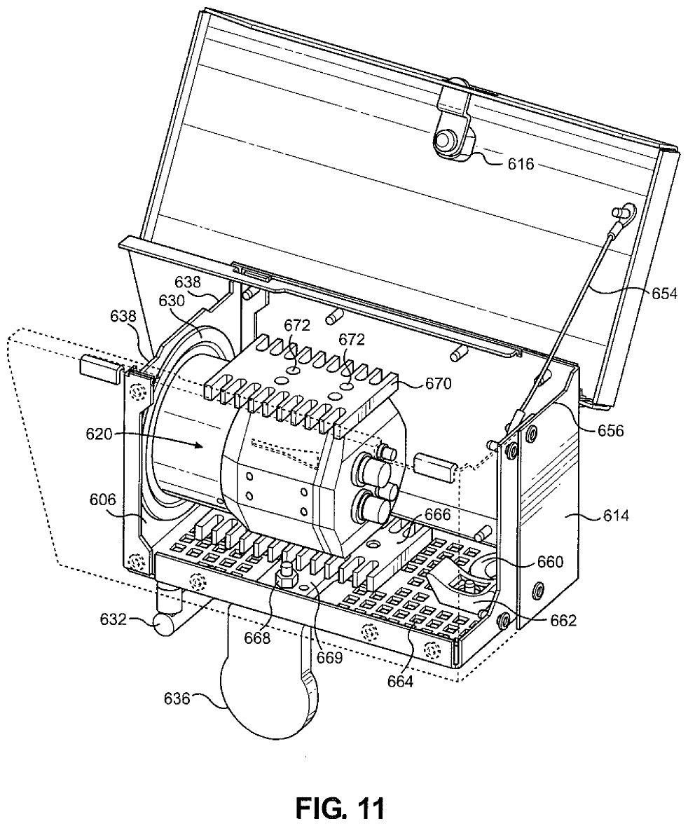

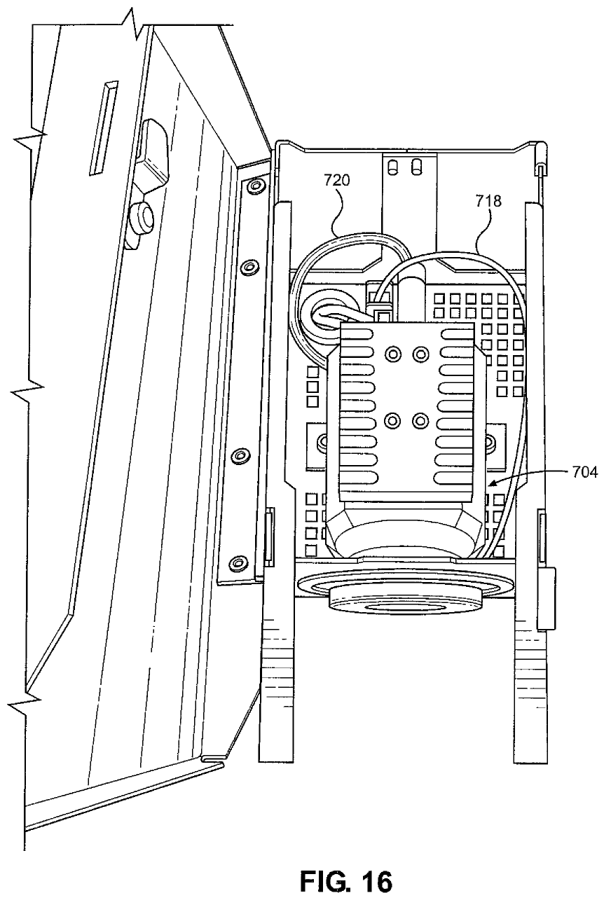

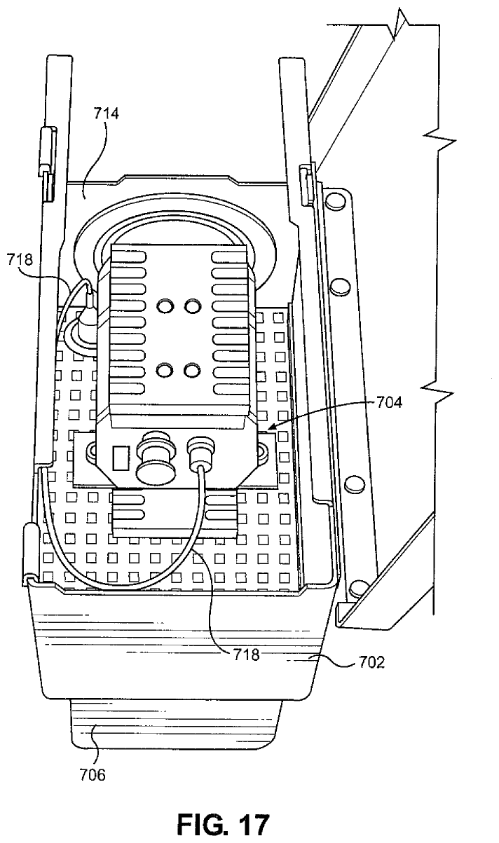

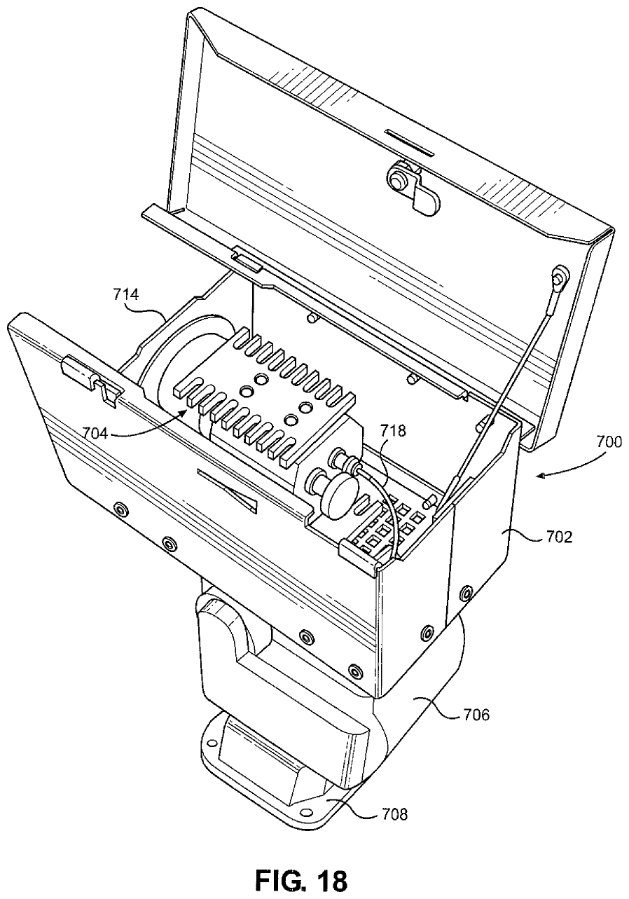

FIGS. 15, 16, 17 and 18 are internal views of the imaging system of FIG. 14 with the lid open and showing the placement of the antenna interface cable 718 and video output cable 720 passing through the cable access port (not shown in this figure, see 660 shown in FIG. 11). Also, the position of infrared imaging device 712 and visual imaging device 710 on front panel 714 is shown.

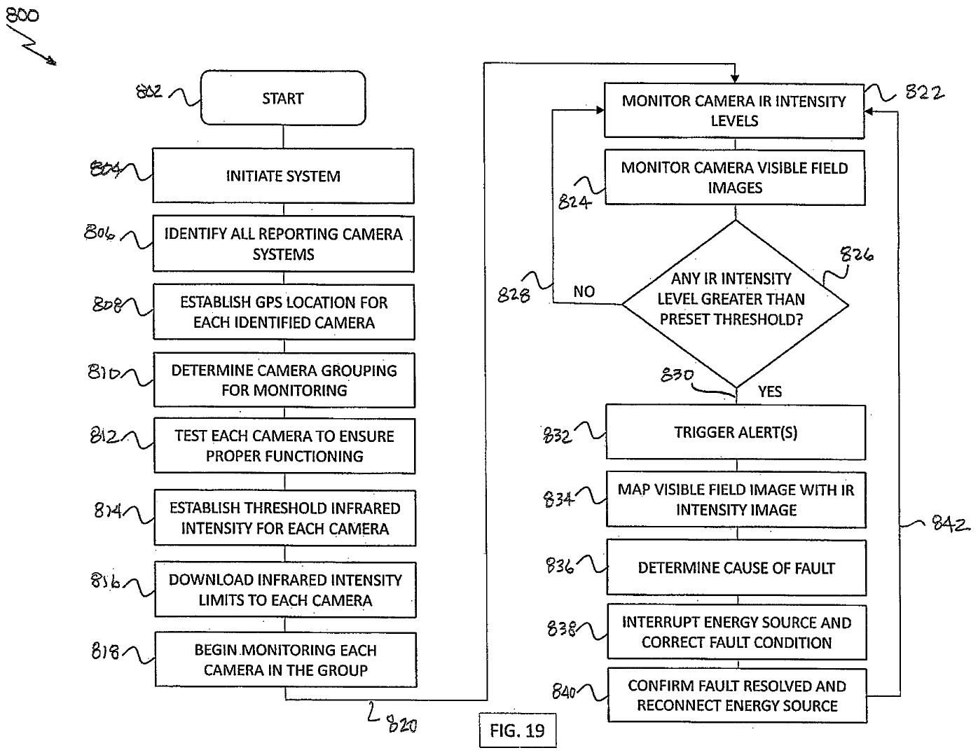

Referring now to FIG. 19, a flow chart 800 depicting the method steps by which the Real-Time Fault Detection and Infrared Inspection System of the present invention is shown. The steps begin in step 802 with a start and the system is initiated in step 804. Each camera is identified in step 806 and a GPS location is determined in step 808. Collective grouping is made in step 810 for monitoring purposes, each camera is tested in step 812, and a threshold infrared limit is established in 814. The preset infrared limit is downloaded to each camera in step 816, and each camera begins monitoring in step 818.

The cameras continue to monitor infrared intensity in step 822, and visual imaging is monitored in step 824. If no infrared intensity level is higher than the preset limit, the method returns on path 828 to continue monitoring the cameras. However, if a high condition is measured in step 826, alerts are triggered in step 832, the visual field is mapped with the infrared field to combine an image for operator viewing in step 834, and the cause of the fault is determined in step 836. If necessary, the energy source is interrupted in step 838, and once the fault is resolved, the energy source can be reconnected to the system in step 840. Once reconnected, monitoring continues in path 842 to step 822.

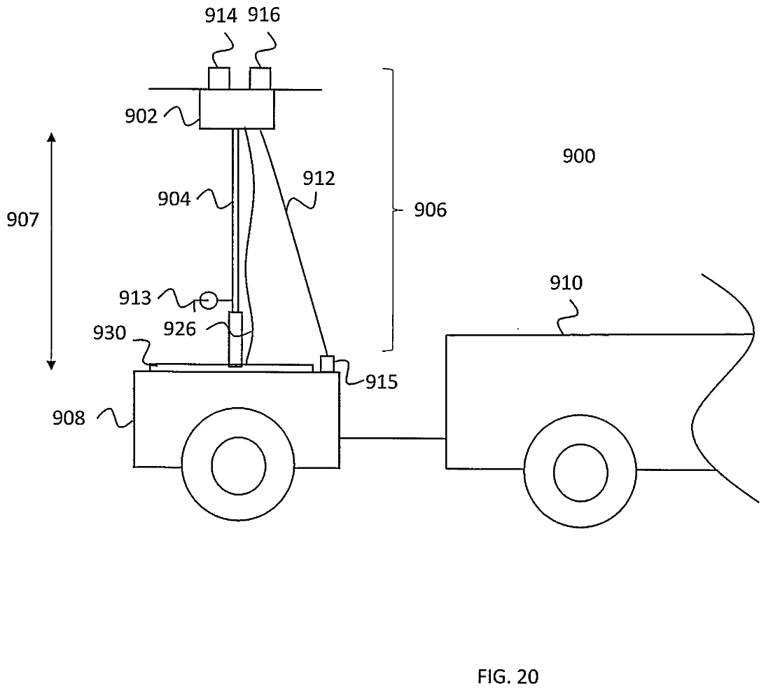

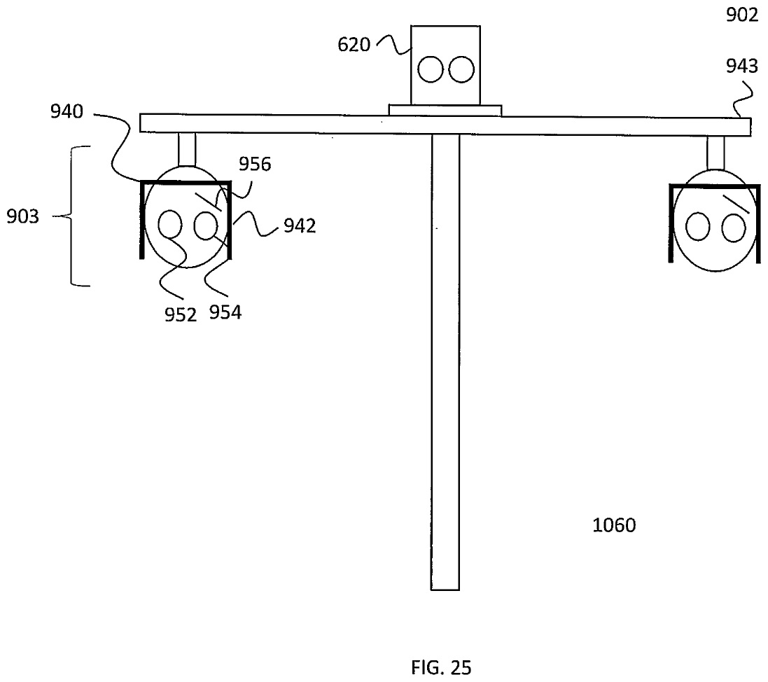

Referring now FIG. 20, an alternative embodiment of the Real-Time Fault Detection and Infrared Inspection System of the present invention, generally designated Mobile Inspection Unit 900, is shown. Mobile Inspection Unit 900 includes telescopic mast assembly 906 which is made up by imaging system 902 and telescopic mast 904. Imaging system 902 operates in a similar manner to the fixed imaging system 100 that was discussed above and is made up by dual imaging camera 620 and camera unit 903 (each discussed at FIG. 25). Additionally, imaging system 902 may be equipped with a PTZ component that allows imaging system 902 to rotate 360 degrees, pan and tilt upwards or downwards to allow thorough inspection of all the equipment in a given area.

Imaging system 902 is affixed to the top of telescoping mast 904 so that imaging system 902 can be positioned at a specific height. Also, two-way loudspeaker 914 and PTZ mounted spotlight 916 are also affixed atop telescoping mast 904. Two-way loudspeaker 914 will enable direct communication to occur between an on-site worker and operator, or it can serve as an audio alarm for when a specific event occurs within the site such as fire or a break-in. PTZ mounted spotlight 916 will also provide added security measures and improved supervision of an area by providing a light source with a high degree of coverage.

To achieve a specific height, telescoping mast 904 can be raised or lowered along direction 907 in order to obtain an optimal viewing position, or to protect the imaging system 902 during transit. Telescoping mast 904 can be raised or lowered by hand crank 913. It is fully envisioned that telescoping mast 904 can be raised or lowered by means other than just hand crank 913 such as, a motorized crank, a hydraulic lift or any other means that is known in the art. Post tension cables 912 will be able to provide additional stability to telescopic mast 904 regardless of whether telescopic mast 904 is in the raised or lowered position. When in the raised position, post tension cables 912 will be able to stabilize telescopic mast 904 in the event of a high wind situation. While telescopic mast 904 is in the lowered position, post tension cables 912 will stabilize the mast while it is being transported from location to location. It is fully envisioned the post tension cable 912 will be able to be tightened by crank wench 915 that is affixed to the top of trailer 908. Crank wench 915 will be able to allow a user to appropriately secure post tension cable 912 based on the height that telescopic mast 904 is set at. It is also envisioned that post tension cable 912 can be made up of alternative means such as guy wire, or other methods known in the art, and that there may be multiples of post tension cable 912 installed onto trailer 908.

Telescoping mast 904 can be set at a number of different heights. It can be set to raise to its maximum height or some other pre-determined height. This will provide a tremendous amount of flexibility to the operation of Mobile Inspection Unit 900. In a non-limiting example, electrical substations have different equipment layouts due to the specific needs of an area. These different layouts results in different equipment footprints that results in equipment being clustered together or spread-out a given area. Consequently, the variable height that telescoping mast 904 can be set at will allow the Mobile Inspection Unit 900 to perform efficiently and effectively in any given situation.

The mast assembly 906 is mounted to trailer 908 that it can be pulled by a vehicle 910. Vehicle 910 is driven with telescoping mast 904 in the lowered position so that Mobile Inspection Unit 900 can be transported to a new location in a manner that minimizes the risk of damage to mast assembly 906. Mast assembly 906 is secured with post-tension cables 912 to minimize wind and ground vibration that results from the movement of trailer 908 while being pulled in transit by vehicle 910. In a preferred embodiment, three post-tension cables 912 will be used to secure mast assembly 906.

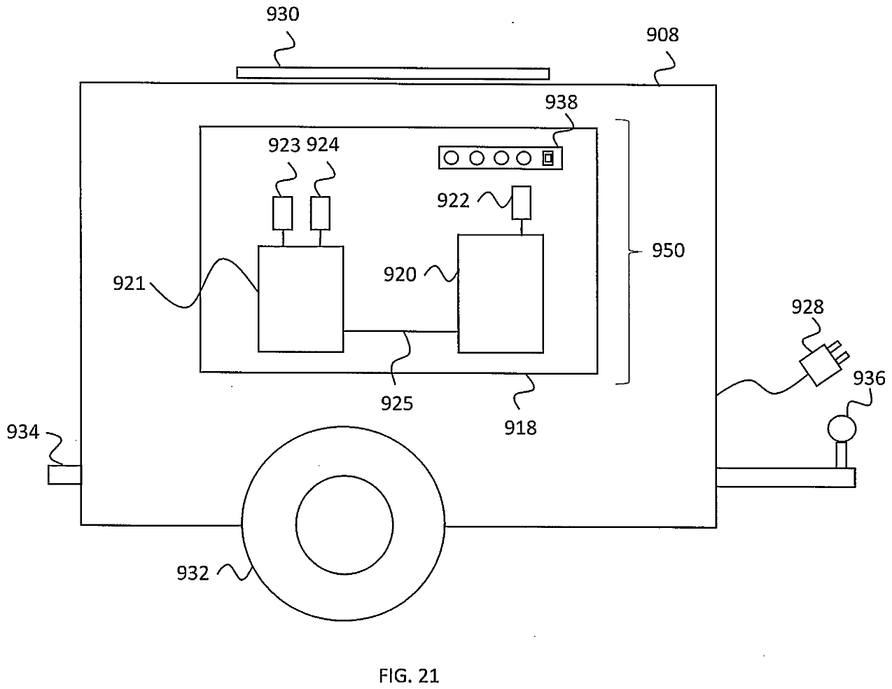

Referring now to FIG. 21, a side view of trailer 908 is shown. Mounted on the side of trailer 908 is control system 950 for Mobile Inspection Unit 900. Control system 950 and imaging system 902 can be powered either by electric plug 928 for a direct connection to a power source, or by solar panel 930 that is mounted on the top surface of trailer 908.

Trailer 908 will be equipped with wheels 932 that can be any kind of readily available tire so that trailer 908 can be easily towed offroad, or on normal road conditions. The wheels have their own electrical brake system installed onto the trailer, this will allow it to not only slow down more efficiently while being towed, but they can be left activated while trailer 908 is parked at a location to minimize the risk of unwanted movement by trailer 908. On one side of trailer 908 is control system 950 and on the other side (not shown) are three different cabinets for storage. The cabinets can either have empty space for storage or have storage drawers installed inside them. Each of the cabinets and control system 950 will have their own doors that are closed and locked with t-handle latches. Receiving hitch 934 will be installed on the back of trailer 908 so that accessories can be mounted onto trailer 908. Trailer coupler 936 will be installed on the front of trailer 908 and is what will allow it to be attached to vehicle 910. For on-road uses, trailer coupler 936 will be a 2-inch ball coupler; while for offroad uses trailer coupler 936 will be an articulating style coupler.

Control system 950 is made up by network box 918 that houses computer 920, router 921, and PoE switch 938. Network box 918 is mounted to the side of trailer 908 so that it is easily accessible for an operator. Computer 920 will have a mounted display unit such as a built-in monitor for displaying a custom dashboard. The custom dashboard will display the built-in widgets that any given site may need; such as a time-temperature graph. The built-in monitor will also be able to display live feeds of all the installed cameras, regardless of whether the camera is for visual or thermal inspection. Computer 920 will also be programmed to record the live feed and take snapshots when critical events, such as the crossing of the temperature threshold, occurs. Lastly, all of the recorded footage can be locally accessed, or exported to a control station some distance away. It is fully envisioned that remote control system can be at a work site some distance away and displayed on a computer, or be an application that can be installed onto a site supervisors smartphone or tablet.

To achieve the above tasks, Computer 920 is in constant bidirectional communication with imaging system 902. This can be achieved either through direct wiring 926 (shown in FIG. 20), an antenna connection, or any other means known in the art. Computer 920 is then able to send the data received from imaging unit 902 to either a local or remote control station. The control station that control system 950 communicates with will operate very similar as discussed for control center 407 as discussed for FIG. 2.

Communication between control system 950 and a control station can be either a direct wired connection, an antenna connection, a wireless connection, or some other means known in the art. If a wireless connection is used then that will be facilitated by router 921 that is also located within network box 918. Router 921 and computer 920 will communicate bidirectionally with each other through communication link 925. Router 921 will be able to bidirectionally communicate wirelessly with a control center either through WiFi Adapter 924, LTE Adapter 923, or some combination of both. Lastly, computer 920 will have GPS sensor 922 installed so that computer 920 can transmit the precise location of mobile inspection unit 900 to an operator.

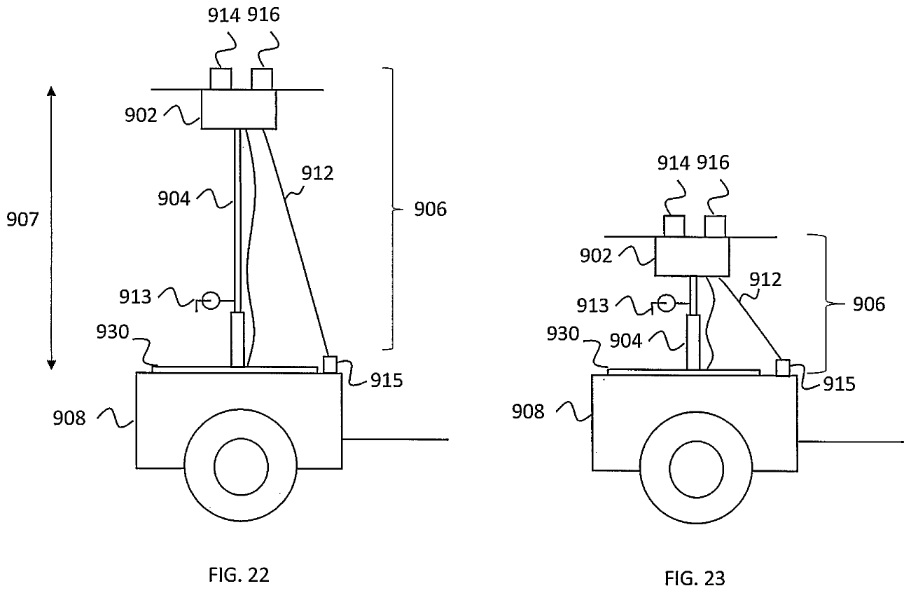

Referring now to FIG. 22 and FIG. 23, a side view of mast assembly 906 in the raised and lowered position is shown. In both views, mast assembly 906 is attached to trailer 908. When telescopic mast 904 is shown in the raised position post-tension cables 912 are used to secure the mast. It is fully envisioned that other means known in the art for raising telescopic mast 904 can be used in other embodiments of Mobile Inspection Unit 900. When mast assembly is fully lowered, imaging system 902 will be protected from high winds, or ground vibrations that result from transit, or to obtain optimal imaging if the location so requires it.

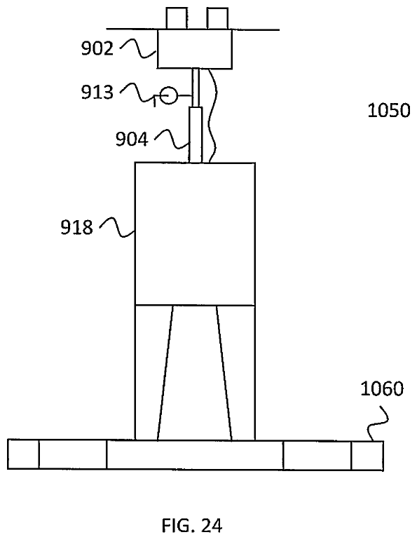

Referring now to FIG. 24, a back view of Mobile Inspection Unit 900 is shown. In this embodiment, generally designated as system 1050, shows mast assembly 906 in the lowered position. The major difference in this embodiment as opposed to others is that mast assembly 906 is mounted to semi-permanent base 1060. Semi-permanent base 1060 will still enable mobile inspection unit 900 to be relocated as needed, but instead of being transported with a vehicle 910 and trailer 908, semi-permanent base 1060 can be moved by other means such as a forklift. This embodiment of Mobile Inspection Unit 900 will still allow the entire system to be easily relocated to a new location by mounting it onto the back of a standard trailer, while also allowing to be relocatable within a given location that may not have continual access to a vehicle.

Referring now to FIG. 25, a front view of imaging system 902 for Mobile Inspection Unit 900 is shown. In this embodiment, imaging system 902 is shown to made up of dual imaging camera 620 and two separate camera units 903. Both of these camera units 903 will be fixed to their own PTZ mounting bracket 942 which will provide each camera unit 903 panning, tilting, and zooming capability. In addition, each PTZ mounting bracket will be attached to beam 943 via rotating base 940 so that each camera unit 903 is able to rotate a full 360°. As such, each camera unit 903 will have a wide range of different viewing angles that can either be preprogrammed into the unit or controlled manually by an operator at some remote distance away.

Further, each camera unit 903 will have similar functionality to dual imaging camera 620 as discussed above. Each camera unit 903 will be able to record simultaneous optical and thermal imaging due to visual imager 952 and thermal imager 954. The main advantage of the placement of each camera unit 903 relative to dual imaging camera 620 is that camera unit 903 will be able to monitor the areas that dual imaging camera 620 will be unable to view due to its movement being restricted to only vertical movement. Further, each camera unit 903 will have a wiper 956 mounted, which will allow for camera unit 903 to wipe away any obstruction blocking the view of both thermal imager 954 and optical imager 952. Thus, in this embodiment, each Mobile Inspection Unit 900 will have built in redundancy to allow for more efficient and effective operation.

Thermal imager 954 will be particularly useful for the detection of potential electrical failure and other types of fire by having a pre-set temperature threshold programmed into control system 950. This will be useful for the monitoring of electrical substations and high-risk fire areas. In addition to having a pre-set temperature programmed into control system 950, a fire detection algorithm will also be installed into control system 950. This algorithm will allow mobile inspection unit 900 to detect any fire or smoke up to 1.8 miles away from the location of the entire unit.

Visual imager 952 will be useful for a couple of different uses. One such use is that visual imager 952 will be able to provide visual confirmation of any condition that activates an alarm. A second major use is that visual imager will be able to conduct security surveillance of the entire site. Control system 950 will also be equipped with a deep learning algorithm that will allow visual imager 952 to understand the different habits that are unique to each location. This will make the detection of any anomalies, such as unauthorized access, much easier to detect at a higher rate of efficiency.

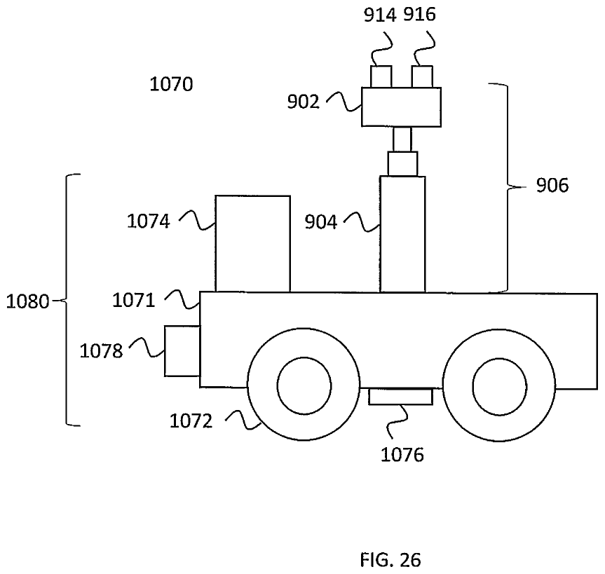

Referring now to FIG. 26, an alternative embodiment of the Mobile Inspection Unit 900 is shown. This embodiment of Mobile Inspection Unit 900 is generally designated as system 1070 and is capable of autonomous movement. Imaging system 902 and telescopic mast assembly 906 will operate similar to the functionality outlined above. However, a significant advantage of system 1070 is that system 1070 will be capable of autonomous movement due to RC system 1080. RC system 1080 consists of base 1071, wheels 1072, navigation module 1074, battery pack 1078, and motor unit 1076. Navigation module 1074 is capable of geo-positioning the entire unit and stay in constant communication with motor unit 1076 to provide instructions. As such, navigation module 1074 is the item that will allow system 1070 to move around a site autonomously. Further, if multiple units of system 1070 are on site, then each individual unit will be able to communicate with each other to ensure adequate coverage of the site and to avoid collisions. Battery pack 1078 is what provides power to the entire unit and it is envisioned that battery pack 1078 can be replaced, or recharged.

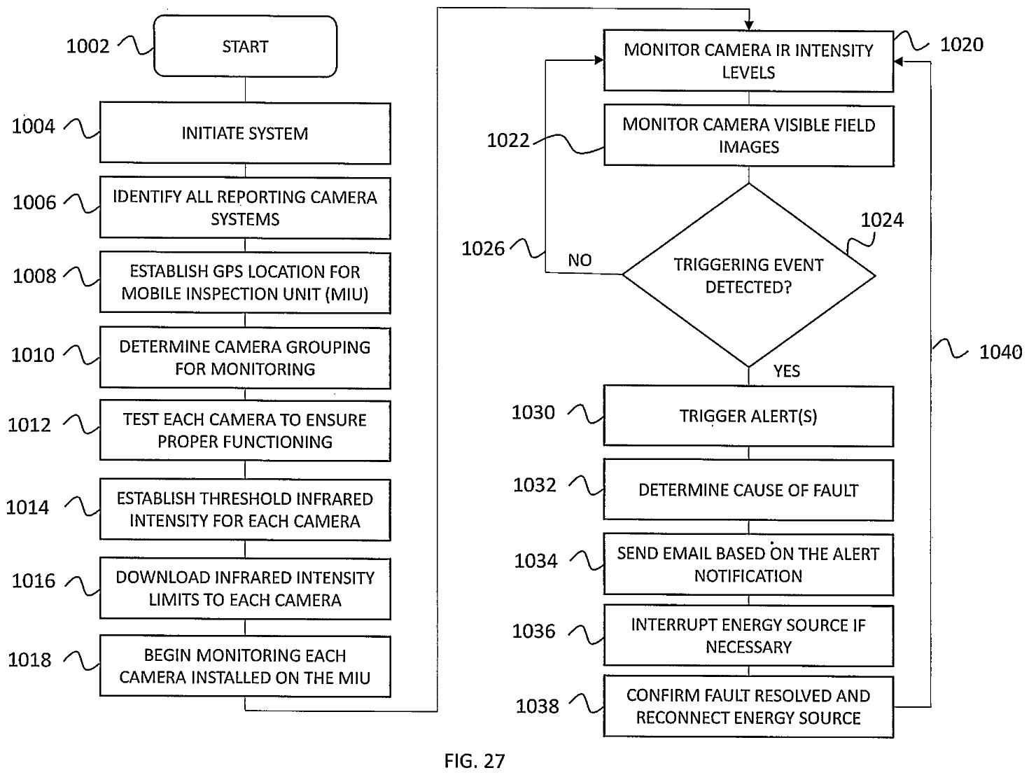

Referring now to FIG. 27, a flow chart 1000 depicting the method steps by which the control station will operate for Mobile Inspection Unit 900. The steps begin in step 1002 with a start and the system is initiated in step 1004. Each camera installed on Mobile Inspection Unit 900 is identified in step 1006 and a GPS location for the entire unit is determined in step 1008. Collective grouping is made in step 1010 for monitoring purposes, each camera is tested in step 1012, and a threshold infrared limit is established in 1014. The preset infrared limit is downloaded to each camera in step 1016, and each camera begins monitoring in step 1018.

The cameras continue to monitor infrared intensity in step 1020, and visual imaging is monitored in step 1022. If no triggering event at step 1024 is detected, the method returns on path 1026 to continue monitoring the cameras. However, if a triggering event is detected in step 1024, alerts are triggered in step 1030, the cause of the fault is determined by an image recognition software algorithm in step 1032, and an image is sent to users showing what triggered the alert in step 1034. If necessary, the energy source is interrupted in step 1036, and once the fault is resolved, the energy source can be reconnected to the system in step 1038. Once reconnected, monitoring continues in path 1040 to step 1020.

While what has been shown is presently considered to be the preferred embodiments of the present invention, it will be apparent to those skilled in the art that various changes and modifications can be made herein without departing from the scope and spirit of the invention.

I claim:

1. A mobile real-time monitoring system for high-voltage electrical equipment comprising:
a trailer that is towable by a vehicle;
a telescopic mast that is mounted atop said trailer,
wherein said telescopic mast has a hand crank that is capable of lowering and raising said telescopic mast,
a beam mounted atop telescopic mast;
an imaging system that is attached to said beam, and
wherein said imaging system further comprises a thermal imager and optical imager.

2. The mobile real-time monitoring system of claim 1, wherein said imaging system is mounted onto a PTZ bracket.

3. The mobile real-time monitoring system of claim 1, wherein said PTZ bracket is attached to a rotatable base, wherein said rotatable base is attached to said beam.

4. The mobile real-time monitoring system of claim 3, wherein said trailer further comprises a network box that contains a computer and router.

5. The mobile real-time monitoring system of claim 4, wherein said network box is in bidirectional communication with said imaging system.

6. The mobile real-time monitoring system of claim 5, wherein said network box is in bidirectional communication with a control station.

7. The mobile real-time monitoring system of claim 6, wherein said trailer is powered by an electrical plug.

8. The mobile real-time monitoring system of claim 7, wherein said trailer has a solar panel mounted on the top.

9. A mobile real-time monitoring system for high-voltage electrical equipment comprising:
an autonomous vehicle base,
wherein said autonomous vehicle base further comprises a navigation module, a motor unit, and a battery pack;
a telescopic mast that is mounted atop said autonomous vehicle base;
an imaging system that is mounted atop said telescopic mast, and
wherein said imaging system further comprises a thermal imager and optical imager.

10. A mobile real-time monitoring system of claim 9, wherein said navigational module is capable of geo-positioning said mobile real-time monitoring system.

11. A mobile real-time monitoring system of claim 10, wherein said battery is rechargeable.
